(19) United States
(12) Patent Application Publication
(10) Pub. No.: US 2026/0255732 A1
(43) Pub. Date: Aug. 27, 2026

(54) QUANTUM WELL-BASED OPTOELECTRONIC DEVICE

(71) Applicant: Hyperlume Inc., Ottawa (CA)

(72) Inventors: Mohsen Asad, Ottawa (CA); Hossein Fariborzi, Auburndale, MA (US); Bilal Janjua, Toronto (CA)

(73) Assignee: Hyperlume Inc., Ottawa (CA)

(21) Appl. No.: 19/065,917

(22) Filed: Feb. 27, 2025

(51) Int. Cl. H10H 20/812; H10H 20/01; H10H 20/815; H10H 20/816; H10H 20/825

(52) U.S. Cl. CPC H10H 20/812; H10H 20/0137; H10H 20/815; H10H 20/8162; H10H 20/825

(57) ABSTRACT

The present disclosure provides a quantum well-based optoelectronic device. A buffer layer is disposed over a substrate. A first conductivity-type semiconductor layer is positioned over the buffer layer, wherein the first conductivity-type semiconductor layer comprises a first-doped layer and a second lower doped layer. A superlattice sheet is positioned over the low doped or undoped semiconductor layer, wherein the superlattice sheet comprises alternating layers of semiconductor materials. A quantum well structure is positioned over the superlattice sheet, wherein the quantum well structure comprises at least one quantum well layer and at least one barrier layer. A first conductivity-type electron blocking film is positioned over the quantum well structure. A second conductivity-type semiconductor layer is disposed over the first conductivity-type electron blocking film. A first contact layer is disposed over the second conductivity-type semiconductor layer.

### TECHNICAL FIELD

The present disclosure generally relates to optoelectronic devices. Further, the present disclosure particularly relates to a quantum well-based optoelectronic device.

### BACKGROUND

Generally, high-speed micro light-emitting diodes (micro-LEDs) are widely utilized in applications that require rapid optical modulation and efficient light emission. Such applications include high-resolution display panels, optical interconnects, visible light communication (Li-Fi), augmented reality systems, and biomedical imaging. The performance of micro-LEDs is determined by several factors, including the design of the quantum well structure, the material composition of active and barrier layers, and the doping profile within critical regions. Among these, the doping strategy used within the barrier layers of the active region significantly affects carrier injection efficiency, charge confinement, and recombination processes, all of which influence the modulation bandwidth and overall device reliability.

Moreover, various doping techniques have been implemented in micro-LEDs to improve carrier injection and achieve uniform charge distribution. Conventionally, uniform doping is applied across the barrier layers to enhance carrier transport and increase radiative efficiency. However, one of the primary challenges associated with uniform doping is the uncontrolled diffusion of dopants into adjacent quantum wells (QWs) during high-temperature growth and subsequent processing steps. Such dopant diffusion can result in defect states within the QWs, leading to increased non-radiative recombination, carrier loss, and performance degradation. For instance, in p-type layers, magnesium (Mg) is commonly used as an acceptor dopant, while in n-type layers, silicon (Si) is frequently used as a donor dopant. During epitaxial growth, mentioned dopants may diffuse from the barrier layers into the QWs, creating unintentional impurity states. Such impurity states act as recombination centers, leading to a decline in internal quantum efficiency (IQE) and a reduction in the achievable modulation speed of the micro-LEDs.

Further, to mitigate the impact of dopant diffusion, alternative doping techniques such as graded doping profiles have been explored. Graded doping involves gradually varying the doping concentration along the thickness of the barrier layers to create a built-in electric field that enhances carrier transport while minimizing recombination losses. The graded doping profile allows for better carrier injection and reduces series resistance, thereby improving power efficiency and increasing modulation bandwidth. However, the implementation of graded doping introduces complexities in material growth, as precise control of doping concentration is required to maintain uniformity across the wafer. Additionally, graded doping may lead to variations in band alignment, necessitating further optimization to prevent undesired carrier leakage.

Another approach employed in micro-LED fabrication is delta doping, wherein dopants are confined within a very thin atomic-scale region, typically at an interface, to enhance carrier confinement while minimizing unintended diffusion. Delta doping provides an effective way to create highly localized charge distributions, leading to improved radiative recombination rates. However, the effectiveness of delta doping depends on optimized growth conditions to make sure that the dopants remain within the intended atomic planes without spreading into adjacent layers. Uncontrolled delta doping may cause band bending effects, altering the carrier transport properties in an unintended manner.

Additionally, co-doping strategies have also been explored as a method to suppress dopant diffusion while maintaining high activation efficiency. In such approaches, secondary elements such as oxygen, germanium, or carbon are introduced alongside primary dopants to stabilize their position within the lattice. Such stabilization prevents dopant migration during high-temperature growth and annealing processes, preserving the intended electronic properties of the barrier layers. Despite these advantages, co-doping requires precise calibration of dopant ratios to avoid unwanted compensatory effects, which could degrade carrier injection efficiency.

In addition to modifying the barrier layers, the incorporation of electron-blocking layers (EBLs) with specific doping profiles has been investigated to mitigate carrier overflow and leakage. Electron-blocking layers are typically implemented using materials with a higher bandgap to restrict electron escape from the active region while promoting hole injection. However, improper doping within the EBLs can lead to charge accumulation at the interfaces, increasing resistance and lowering overall efficiency. Furthermore, unoptimized EBL doping profiles may introduce additional energy barriers, reducing the intended carrier transport efficiency.

Recent advancements have focused on integrating multiple doping techniques within a single device to achieve a balance between carrier confinement, transport efficiency, and high-speed operation. However, several challenges remain in the implementation of advanced doping strategies for micro-LEDs, including difficulties in maintaining dopant activation efficiency, preventing unwanted impurity incorporation, and enabling stable operation under high-frequency modulation conditions.

In light of the above discussion, there exists an urgent need for solutions that overcome dopant diffusion, recombination losses, and resistance-related inefficiencies associated with conventional doping techniques for high-speed micro-LEDs.

### SUMMARY

The present disclosure provides a quantum well-based optoelectronic device. A buffer layer is disposed over a substrate. A first conductivity-type semiconductor layer is positioned over the buffer layer, wherein the first conductivity-type semiconductor layer comprises a first-doped layer and a second-doped layer. A superlattice sheet is positioned over the first conductivity-type semiconductor layer, wherein the superlattice sheet comprises alternating layers of semiconductor materials. A quantum well structure is positioned over the superlattice sheet, wherein the quantum well structure comprises at least one quantum well layer and at least one barrier layer. A first conductivity-type electron blocking film is positioned over the quantum well structure. A second conductivity-type semiconductor layer is disposed over the first conductivity-type electron blocking film. A first contact layer is disposed over the second conductivity-type semiconductor layer. Furthermore, the quantum well-based optoelectronic device enables improved carrier confinement, higher emission efficiency, and enhanced reliability in optoelectronic applications.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein.

Embodiments of the present disclosure will now be described, by way of example only, with reference to the following diagrams.

FIG. 1 illustrates a quantum well-based optoelectronic device, in accordance with the embodiments of the present disclosure;

FIG. 2 illustrates a method for fabricating a quantum well-based optoelectronic device, in accordance with embodiments of the present disclosure;

FIG. 3 illustrates an exemplary diagram for a quantum well structure with barrier layers on both sides of each quantum well layer, in accordance with embodiments of the present disclosure;

FIG. 4 illustrates an exemplary diagram for a quantum well structure with a barrier layer positioned on one side of the quantum well, in accordance with embodiments of the present disclosure;

FIG. 5 illustrates various doping schemes for quantum barriers to influence carrier dynamics and modify device properties, in accordance with embodiments of the present disclosure;

FIG. 6 illustrates various grading schemes implemented in quantum barriers to influence dopant ionization, carrier transport, and barrier height, in accordance with embodiments of the present disclosure; and

FIG. 7 illustrates a quantum barrier incorporating co-doping to modify dopant ionization properties and stabilize charge carrier characteristics, in accordance with embodiments of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

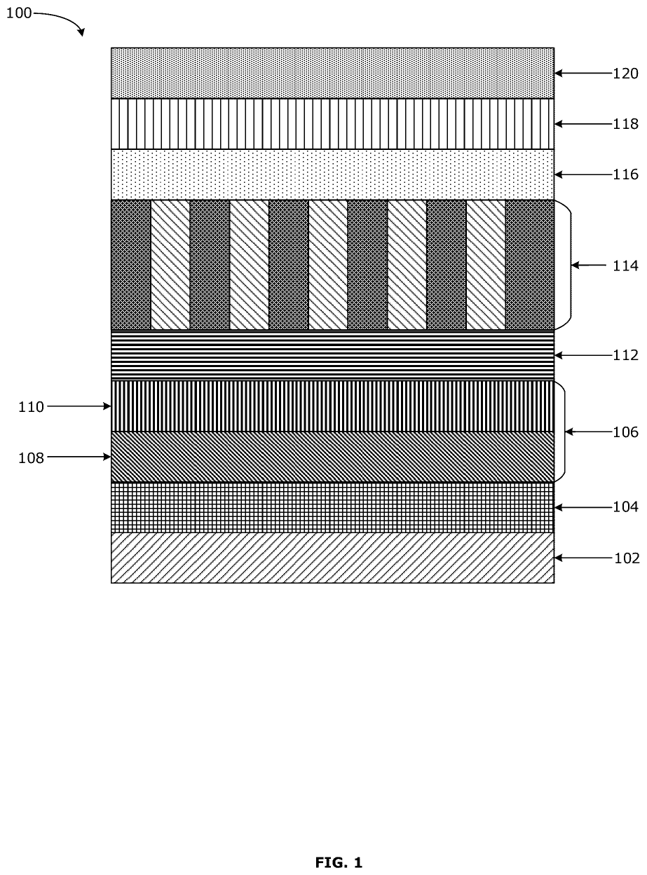

FIG. 1 illustrates a quantum well-based optoelectronic device (100), in accordance with the embodiments of the present disclosure. The quantum well-based optoelectronic device (100) comprises a buffer layer (104) disposed over a substrate (102). The buffer layer (104) provides a transition interface between the substrate (102) and the subsequent layers to manage lattice mismatches and mitigate defect propagation. Various materials are utilized for forming the buffer layer (104) based on the semiconductor system requirements. Examples include Gallium Nitride (GaN) buffers on Silicon (Si) on Sapphire (Al₂O₃) substrates and Indium Phosphide (InP) buffers on Gallium Arsenide (GaAs) substrates. Deposition techniques for such a buffer layer (104) include Molecular Beam Epitaxy (MBE), Metal-Organic Chemical Vapor Deposition (MOCVD), and Hydride Vapor Phase Epitaxy (HVPE), which enable precise control over thickness and material composition. The thickness of the buffer layer (104) varies depending on the specific substrate (102) material and the growth conditions. A typical range for the buffer layer (104) thickness extends from several nanometers to a few micrometers. The buffer layer (104) serves to reduce threading dislocations, which arise due to lattice mismatch between the substrate (102) and the first conductivity-type semiconductor layer (106). The substrate (102) is formed from materials including sapphire (Al₂O₃), Si, silicon carbide (SiC), or GaN, selected based on thermal, electrical, and optical properties suitable for optoelectronic applications. The surface of the substrate (102) is prepared through chemical-mechanical polishing and cleaning processes to achieve optimal epitaxial growth conditions.

In an embodiment, a first conductivity-type semiconductor layer (106) is positioned over the buffer layer (104) and comprises a first-doped layer (108) and a low-doped layer (110). The first conductivity-type semiconductor layer (106) facilitates charge carrier transport within the quantum well-based optoelectronic device (100). The first-doped layer (108) is formed from n-type GaN doped with a donor impurity such as Si to introduce free electrons as majority carriers. The doping concentration of the first-doped layer (108) is controlled to achieve a desired carrier concentration while minimizing ionized impurity scattering. The second-doped layer (110) is positioned over the first-doped layer (108) and comprises a lower doping concentration than the first-doped layer (108). The second-doped layer (110) is an n GaN layer doped with a reduced concentration of Si or other donor elements. This layer functions to increase the width of the depletion region, thereby expanding the intrinsic region. Control over this layer enables the reduction of depletion capacitance. Since the layer is either undoped or lightly doped and positioned on the n-side, electron mobility under the junction field remains uncompromised, ensuring high injection efficiency into the active region. The doping concentration of the second-doped layer (110) is lower than the doping concentration of the first-doped layer (108), assuring optimized electrical characteristics for charge carrier transport. The thickness of the first-doped layer (108) and the second-doped layer (110) is controlled to balance carrier mobility, conductivity and depletion region. The first conductivity-type semiconductor layer (106) is grown using epitaxial techniques such as MOCVD or MBE to maintain high crystalline quality and minimize structural defects. The interface between the first-doped layer (108) and the second-doped layer (110) promotes efficient electron transport. The incorporation of a doping gradient between the first-doped layer (108) and the second-doped layer (110) modulates the energy band structure, thereby improving overall carrier injection efficiency.

In an embodiment, a superlattice sheet (112) is positioned over the first conductivity-type semiconductor layer (106) and comprises alternating layers of semiconductor materials. The superlattice sheet (112) introduces a periodic potential variation, which influences carrier transport and strain distribution within the quantum well-based optoelectronic device (100). The superlattice sheet (112) consists of multiple thin layers of semiconductor materials, each having distinct bandgap properties. The material combinations for the superlattice sheet (112) may comprise alternating layers of GaN and AlGaN, GaAs and AlAs, or InGaN and GaN, depending on the desired electronic and optical characteristics. The superlattice sheet (112) is deposited using controlled epitaxial growth techniques such as MOCVD or MBE, enabling thickness control and compositional uniformity. The periodic arrangement of semiconductor materials in the superlattice sheet (112) facilitates strain compensation, reducing defects and dislocations within the subsequent active layers. The presence of the superlattice sheet (112) modifies the energy band structure by introducing minibands and quantum states, which influence carrier transport and recombination processes. The alternating layers within the superlattice sheet (112) enhance carrier confinement, improving overall optoelectronic performance. The thickness uniformity of each layer within the superlattice sheet (112) is maintained to achieve consistent electronic properties, whereas non-uniform layer thickness is utilized to customize band structure characteristics. This layer may or may not be doped or if doped.

In an embodiment, a quantum well structure (114) is positioned over the superlattice sheet (112) and comprises at least one quantum well layer and at least one barrier layer. The quantum well structure (114) facilitates charge carrier confinement through a heterojunction interface between the quantum well layer and the barrier layer. The quantum well layer is formed from a semiconductor material possessing a bandgap energy lower than that of the adjacent barrier layer to promote electron-hole recombination. The materials utilized for the quantum well layer may include Indium Gallium Nitride (InGaN), Gallium Arsenide (GaAs), and Indium Phosphide (InP), which are selected based on the emission wavelength and electronic properties of the device. Due to variations in thickness or process-induced inhomogeneity, the quantum well can exhibit three-dimensional carrier confinement, resulting in localization effects that enhance radiative recombination efficiency. The quantum well can be configured in various profiles, including square, graded, staircase, or coupled QW designs. The barrier layer, positioned adjacent to the quantum well layer, comprises a material with a higher bandgap energy to restrict carrier movement out of the quantum well region. Such a barrier layer may include Aluminum Gallium Nitride (AlGaN) in GaN-based devices or Aluminum Gallium Arsenide (AlGaAs) in GaAs-based structures. The quantum well structure (114) may incorporate multiple quantum well layers and barrier layers arranged alternately to achieve a desired carrier confinement potential. A doping profile is introduced within the quantum well layer to modify charge carrier distribution, wherein the doping elements may include Si for n-type doping and Magnesium (Mg) for p-type doping. The thickness of each quantum well layer and each barrier layer is controlled through epitaxial growth techniques such as MBE and MOCVD, enabling band structure managing and emission wavelength selection. The quantum well structure (114) influences optical and electrical characteristics based on the layer thickness, material composition, and doping concentration. The quantum well structure (114) supports radiative recombination of carriers, leading to photon emission under electrical excitation.

In an embodiment, a first conductivity-type electron blocking film (116) is positioned over the quantum well structure (114) and restricts electron overflow while facilitating hole transport toward the active region. The first conductivity-type electron blocking film (116) comprises a semiconductor material possessing a bandgap energy greater than that of the quantum well structure (114) to enhance carrier confinement. Materials such as AlGaN and Aluminum Indium Phosphide (AlInP) are utilized for the first conductivity-type electron blocking film (116) based on the semiconductor system employed. The thickness and doping profile of the first conductivity-type electron blocking film (116) reduce electron leakage while enabling efficient hole transport. The first conductivity-type electron blocking film (116) may incorporate a graded composition profile to achieve gradual band alignment, reducing carrier scattering at the heterojunction interface. The first conductivity-type electron blocking film (116) is introduced through epitaxial deposition techniques, including MOCVD and MBE, affirming controlled layer thickness and uniformity. The doping concentration within the first conductivity-type electron blocking film (116) is optimized to balance carrier injection efficiency while preventing excess recombination outside the quantum well structure (114). Variations in doping concentration within the first conductivity-type electron blocking film (116) modify the barrier height for electron transport, thereby influencing charge carrier dynamics. The first conductivity-type electron blocking film (116) contributes to improved carrier confinement and efficiency of the device by directing hole carriers toward the quantum well structure (114) while minimizing electron leakage.

In an embodiment, a second conductivity-type semiconductor layer (118) is disposed over the first conductivity-type electron blocking film (116) and serves as a hole injection region for charge carrier transport. The second conductivity-type semiconductor layer (118) comprises a p-type doped semiconductor material, wherein the doping elements may include magnesium (Mg), Zinc (Zn), or Beryllium (Be) for achieving p-type conductivity. The second conductivity-type semiconductor layer (118) provides an interface for charge carrier recombination by facilitating hole transport toward the quantum well structure (114). The material composition of the second conductivity-type semiconductor layer (118) is selected based on the semiconductor stack, with examples including GaN, GaAs, and InP. The doping concentration of the second conductivity-type semiconductor layer (118) may or may not vary along a direction perpendicular to the quantum well structure (114) to optimize charge carrier injection and band alignment. The second conductivity-type semiconductor layer (118) is deposited using epitaxial growth techniques, such as MOCVD and MBE, assuring controlled thickness and doping profile. The electrical properties of the second conductivity-type semiconductor layer (118) influence carrier transport dynamics, wherein the selection of doping concentration and material composition affects device performance. The thickness of the second conductivity-type semiconductor layer (118) is adjusted based on charge carrier mobility and recombination characteristics. The second conductivity-type semiconductor layer (118) may incorporate a graded doping or bandgap profile to enhance carrier injection efficiency while reducing resistance to hole transport. The doping profile of the second conductivity-type semiconductor layer (118) is optimized to achieve a balance between carrier confinement and transport properties, enabling efficient recombination within the quantum well structure (114). The second conductivity-type semiconductor layer (118) establishes an electrical connection to the first contact layer (120), forming a continuous charge transport pathway.

In an embodiment, a first contact layer (120) is disposed over the second conductivity-type semiconductor layer (118) and provides an electrical interface for charge injection. The first contact layer (120) comprises a highly doped semiconductor material to enable low-resistance electrical contact with external electrodes. The doping elements utilized in the first contact layer (120) include Mg and Zinc (Zn) for p-type conduction in GaN structures. The first contact layer (120) may incorporate a tunnel junction to enhance carrier injection efficiency by reducing contact resistance. The material selection for the first contact layer (120) depends on the optoelectronic device structure, wherein the electrical and optical properties of such a layer influence overall performance. The first contact layer (120) is deposited using techniques such as Physical Vapor Deposition (PVD), Atomic Layer Deposition (ALD), and Sputtering, enabling uniform coverage and minimal surface resistance. The thickness of the first contact layer (120) is selected based on optical transparency and electrical conductivity requirements. The first contact layer (120) interfaces with an external electrode, establishing an electrical connection for current injection into the device. The first contact layer (120) may be structured with surface texturing to reduce reflection losses and improve light extraction efficiency. The doping concentration within the first contact layer (120) is adjusted to minimize contact resistance while preserving charge carrier transport properties. Transparent conductive oxide (TCO) material, such as Indium Tin Oxide (ITO) or Zinc Oxide (ZnO) in conjunction with other metal can then be used to form an ohmic contact to enable optical transmission while maintaining electrical conductivity.

In an embodiment, the second-doped layer (110) may comprise a doping concentration lower than the doping concentration of the first-doped layer (108) by one or two orders of magnitude. The second-doped layer (110) modifies charge carrier distribution and influences electric field characteristics within the semiconductor structure. A doping concentration gradient between the first-doped layer (108) and the second-doped layer (110) influences charge carrier injection and transport properties. Doping elements introduced into the first-doped layer (108) and the second-doped layer (110) include Si for n-type doping and Mg for p-type doping. The doping concentration gradient between the first-doped layer (108) and the second-doped layer (110) is achieved through controlled deposition and doping techniques, assuring a gradual transition that reduces interface defects. The selection of doping concentration within the second-doped layer (110) is based on semiconductor material properties and operational requirements.

In an embodiment, the barrier layer may comprise a graded material composition along a direction perpendicular to a plane of the barrier layer to modify band alignment. A gradual variation in material composition within the barrier layer influences charge carrier confinement and transport dynamics. The material composition of the barrier layer varies based on the semiconductor system, incorporating elements such as Aluminum (Al), Gallium (Ga), and Indium (In) in compound semiconductor materials including AlGaN and AlGaAs. The barrier layer comprises a gradual transition in composition, forming a continuous variation in bandgap energy that modifies charge carrier behavior. The material composition of the barrier layer is controlled using deposition techniques that establish a spatially varying concentration profile. The selection of material composition grading is based on charge carrier injection requirements and bandgap energy alignment. The thickness and composition of the barrier layer influence electron injection and hole transport properties.

In an embodiment, the barrier layer may be doped with a first doping element, wherein the barrier layer comprises a first set of areas that include the first doping element and a second set of areas that remain free from the first doping element. The selective doping of the barrier layer influences charge carrier transport characteristics and modifies carrier recombination properties. The first doping element is introduced based on semiconductor material composition and electronic properties. Examples of first doping elements include Si for n-type doping and Mg for p-type doping in GaN-based structures, while Zinc (Zn) and Carbon (C) are utilized for alternative semiconductor systems. The selective doping of the barrier layer is implemented using controlled doping techniques that define spatially distinct doping regions. The first set of areas within the barrier layer comprises localized doping regions that modify charge carrier injection and confinement, while the second set of areas without the first doping element retains intrinsic semiconductor properties. The spatial doping variation influences charge carrier dynamics, controlling electron leakage and optimizing carrier recombination.

In an embodiment, the first doping element in each of the first set of areas may be introduced using at least one selected from a delta doping technique, a uniform doping technique, and a graded doping technique. The selection of the doping technique influences charge carrier distribution and energy band alignment within the barrier layer. The delta doping technique introduces a highly concentrated layer of doping atoms at a specific depth within the barrier layer, modifying the local charge carrier profile. The uniform doping technique distributes the first doping element evenly throughout the first set of areas, forming a homogenous doping region with a consistent charge carrier concentration. The graded doping technique introduces a progressively varying doping concentration along the depth of the barrier layer, generating a smooth transition in electronic properties. The selection of a doping technique is based on the semiconductor structure and charge carrier transport properties.

In an embodiment, at least one of the first set of areas may be co-doped with a second doping element selected from the group consisting of Silicon (Si), Germanium (Ge), Beryllium (Be), Calcium (Ca), and Zinc (Zn). The introduction of a second doping element modifies charge carrier density and electrical properties of the barrier layer. The second doping element is introduced based on semiconductor material composition and charge carrier dynamics. Co-doping techniques influence carrier mobility, recombination properties, and electrical conductivity within the barrier layer. The selection of the second doping element is based on material compatibility and charge carrier transport characteristics. The concentration of the second doping element is adjusted to maintain an optimal charge carrier distribution within the first set of areas. The interaction between the first doping element and the second doping element modifies electronic properties within the doped regions of the barrier layer. The incorporation of the second doping element influences charge carrier pathways and transport characteristics. The introduction of the second doping element is achieved using controlled doping techniques that enable uniform or spatially varying doping profiles.

In an embodiment, each quantum well layer and each barrier layer may be associated with a variable thickness to control emission wavelength and optimize electron-hole recombination. The thickness variation of the quantum well layer influences the quantum confinement energy levels, modifying the emission spectrum. A thinner quantum well layer increases quantum confinement, leading to higher energy photon emission, whereas a thicker quantum well layer reduces confinement, resulting in longer wavelength emission. The barrier layer thickness determines the coupling strength between adjacent quantum well layers in multi-quantum well structures, influencing carrier dynamics. The variation in thickness of the quantum well layer and the barrier layer is achieved using deposition techniques that control material growth rate and layer uniformity. The quantum well layer and the barrier layer are formed from semiconductor materials such as InGaN, GaAs, and InP, selected based on emission wavelength requirements. The thickness profile of each quantum well layer and each barrier layer is determined by growth parameters, including temperature, precursor flow rate, and deposition duration.

In an embodiment, the second conductivity-type semiconductor layer (118) may be doped with a third doping element, wherein the concentration of the third doping element changes along the direction perpendicular to the plane of the quantum well layer and the barrier layer. The graded doping profile influences charge carrier transport by modifying the band structure and internal electric field within the semiconductor layer. A higher doping concentration near the interface with the first conductivity-type electron blocking film (116) reduces contact resistance and promotes hole injection, while a lower doping concentration in regions near the first contact layer (120) minimizes excess carrier scattering. The third doping element is selected based on the material composition of the second conductivity-type semiconductor layer (118) and may include Mg for GaN-based structures or Zn for GaAs-based structures. The doping concentration gradient is achieved using controlled deposition and doping techniques that regulate dopant incorporation during semiconductor layer formation.

In an embodiment, a thickness of each layer of the semiconductor material in the superlattice sheet (112) may be uniform. The uniform thickness of each alternating layer within the superlattice sheet (112) influences electronic band structure properties and carrier transport characteristics. The superlattice sheet (112) comprises periodic layers of semiconductor materials with distinct compositions, forming a potential well structure that affects charge carrier mobility. A uniform thickness of each layer establishes consistent confinement conditions, reducing variability in charge transport and energy band alignment. The thickness of each layer is maintained using deposition techniques that control material growth rate, composition, and layer interface quality. The superlattice sheet (112) is formed from materials such as GaN, InGaN and AlGaN in III-nitride semiconductor systems or GaAs and AlAs in III-V compound semiconductor structures. The uniformity in thickness is determined by deposition parameters, including temperature stability, precursor flow rate, and substrate rotation speed. The selection of uniform thickness is based on device requirements for band structure engineering and carrier mobility control.

In an embodiment, the thickness of each layer of the semiconductor material in the superlattice sheet (112) is non-uniform. A variation in thickness influences charge carrier dynamics by modifying energy band alignment and tunneling probabilities. A thicker layer in certain regions alters the potential barrier height, modifying the movement of charge carriers between adjacent layers. A thinner layer in selected areas increases wavefunction overlap, enhancing quantum coupling effects. The non-uniform thickness profile is established using deposition techniques that control layer growth rate, composition distribution, and interface roughness. The superlattice sheet (112) comprises alternating layers of semiconductor materials selected based on bandgap energy and lattice compatibility, including GaN, AlGaN, InGaN GaAs, and AlAs. The thickness variation is controlled by adjusting deposition parameters such as precursor flow rate, substrate temperature, and growth duration.

In an embodiment, an interlayer may be disposed at an interface between each quantum well layer and each adjacent barrier layer. The interlayer modifies strain distribution, reducing defect formation at the heterojunction interface. The interlayer influences charge carrier transport by modifying band alignment and interface recombination characteristics. The interlayer is formed from a semiconductor material with an intermediate bandgap energy between the quantum well layer and the barrier layer, reducing energy discontinuity at the interface. The interlayer material is selected based on lattice compatibility and bandgap energy, including AlGaN, AlGaInN, AInN InGaN in III-nitride structures and InGaAs in III-V compound semiconductor systems. The interlayer thickness is controlled using deposition techniques that establish a consistent transition region between the quantum well layer and the barrier layer.

In an embodiment, the first contact layer (120) may comprise a tunnel junction to provide a low-resistance electrical contact. The tunnel junction consists of a heavily doped (doping concentration >10²⁰ cm³) semiconductor interface that facilitates quantum mechanical tunneling of charge carriers, reducing the potential barrier for carrier injection. The tunnel junction enables efficient charge transport by allowing electrons or holes to pass through the depletion region via quantum tunneling rather than thermionic emission. The tunnel junction is formed from a semiconductor material with a high doping concentration to enable sufficient carrier density at the junction. Examples of materials used for the tunnel junction include heavily doped GaN, ITO, and InGaN, selected based on band alignment and electrical conductivity requirements. The thickness of the tunnel junction is optimized to balance tunneling probability and resistivity. The doping concentration is controlled to achieve an optimal band bending effect, allowing for effective tunneling of charge carriers. The tunnel junction is formed using semiconductor deposition techniques that establish a controlled doping gradient and interface stability. The selection of tunnel junction materials and doping profiles is based on electrical conductivity, charge carrier injection efficiency, and compatibility with the surrounding layers. The tunnel junction structure influences the overall electrical performance of the first contact layer (120), contributing to improved charge carrier transport within the quantum well-based optoelectronic device (100).

In an embodiment, each quantum well layer may be, individually, doped with a fourth doping element with a preset concentration. The doping of each quantum well layer modifies charge carrier distribution, recombination properties, and internal electric field characteristics. The fourth doping element is introduced based on semiconductor composition and charge carrier dynamics, with examples including Si for n-type doping and Mg for p-type doping. The doping concentration is maintained within a predefined range to avoid excessive carrier depletion or scattering effects. The introduction of the fourth doping element influences quantum confinement properties by altering the charge carrier density within the quantum well layer (what is a fourth doping element?). The incorporation of the fourth doping element is achieved through controlled deposition and doping techniques that enable uniform dopant distribution. The doping concentration is selected based on the emission wavelength, band structure alignment, and carrier recombination requirements of the quantum well layer. The uniformity of the doping profile minimizes inhomogeneous charge carrier distribution, maintaining consistent recombination rates. The thickness of the quantum well layer is adjusted in conjunction with the doping concentration to achieve the desired electronic and optical properties. The selection of the fourth doping element and concentration profile is determined based on semiconductor material characteristics, carrier lifetime requirements, and operational conditions of the quantum well-based optoelectronic device (100).

In an embodiment, the concentration of the fourth doping element may vary in the direction perpendicular to the plane of the quantum well layer to adjust at least one parameter of each quantum well layer, wherein the parameter is selected from an energy band offset, an electron confinement property, and a hole confinement property. A graded doping profile influences charge carrier dynamics by creating a gradual variation in electronic properties across the quantum well layer. The variation in doping concentration modifies the energy band offset, controlling charge carrier confinement strength. A higher doping concentration near the quantum well layer interface enhances charge carrier accumulation, whereas a lower doping concentration in central regions influences carrier recombination characteristics. The variation in doping concentration is introduced using deposition techniques that establish a controlled spatial doping gradient. The selection of the doping concentration variation is based on the semiconductor material properties, emission wavelength tuning requirements, and charge carrier transport behavior. A graded doping profile modifies the electric field distribution across the quantum well layer, reducing carrier scattering and optimizing recombination efficiency. The variation in doping concentration also influences strain distribution within the quantum well structure, affecting material stability. The doping profile is adjusted based on device operational requirements to achieve optimized electron-hole confinement and emission wavelength control.

In an embodiment, the quantum well structure (114) may comprise the quantum well layers and the barrier layers alternately and parallelly arranged, wherein the quantum well layers and the barrier layers are disposed orthogonally to the superlattice sheet (112). The arrangement of the quantum well layers and the barrier layers influences charge carrier confinement properties and recombination efficiency. The quantum well structure (114) is formed using semiconductor materials selected based on bandgap energy alignment, lattice compatibility, and optical emission characteristics. The parallel arrangement of the quantum well layers and the barrier layers allows for periodic confinement of charge carriers, influencing energy band structure and transition probabilities. The quantum well structure (114) is deposited using semiconductor growth techniques that establish uniform layer thickness and interface quality. The spacing and thickness of the quantum well layers and the barrier layers are adjusted to modify charge carrier movement and recombination dynamics. The quantum well structure (114) relative to the superlattice sheet (112) is determined based on the strain management properties and band structure engineering requirements. The selection of material composition, doping concentration, and layer arrangement influences charge carrier lifetime and recombination rate within the active region. The integration of the quantum well structure (114) with the superlattice sheet (112) is controlled to maintain structural stability and minimize defect formation.

In an embodiment, the first conductivity-type semiconductor layer (106) may comprise a stacked semiconductor arrangement, wherein the stacked semiconductor arrangement comprises alternating layers of a semiconductor composition selected from the group consisting of GaN, InGaN, AlGaN, AlInN, and AlGaInN. The stacked semiconductor arrangement influences charge carrier injection properties, bandgap alignment, and strain management within the semiconductor structure. The alternating layers within the stacked semiconductor arrangement are deposited with controlled thickness and composition to modify electronic and optical properties. The material selection for the stacked semiconductor arrangement is based on lattice compatibility, charge carrier mobility, and energy band characteristics. The thickness of each layer in the stacked semiconductor arrangement is adjusted to influence carrier recombination dynamics and band structure alignment. The stacked semiconductor arrangement is integrated using semiconductor growth techniques that establish controlled layer thickness, doping concentration, and interface quality. The selection of semiconductor compositions within the stacked semiconductor arrangement influences charge carrier transport pathways, carrier lifetime, and optical emission characteristics.

In an embodiment, the first conductivity-type electron blocking film (116) may be fabricated from a material with a bandgap greater than the quantum well layer. The bandgap energy of the first conductivity-type electron blocking film (116) influences electron blocking properties, restricting electron overflow while allowing hole transport into the active region. The material composition of the first conductivity-type electron blocking film (116) is selected based on charge carrier blocking efficiency and semiconductor compatibility. Examples of materials include AlGaN in III-nitride semiconductor systems and Aluminum Indium Phosphide (AlInP) in III-V compound semiconductor structures.

In an embodiment, the second conductivity-type semiconductor layer (118) may comprise a temperature-stabilized doped region. The doping profile of the second conductivity-type semiconductor layer (118) is selected based on thermal stability requirements, charge carrier transport efficiency, and band alignment properties. The temperature-stabilized doped region maintains electrical conductivity and charge carrier mobility under varying thermal conditions. The doping concentration of the temperature-stabilized doped region is adjusted based on material properties and charge carrier injection requirements.

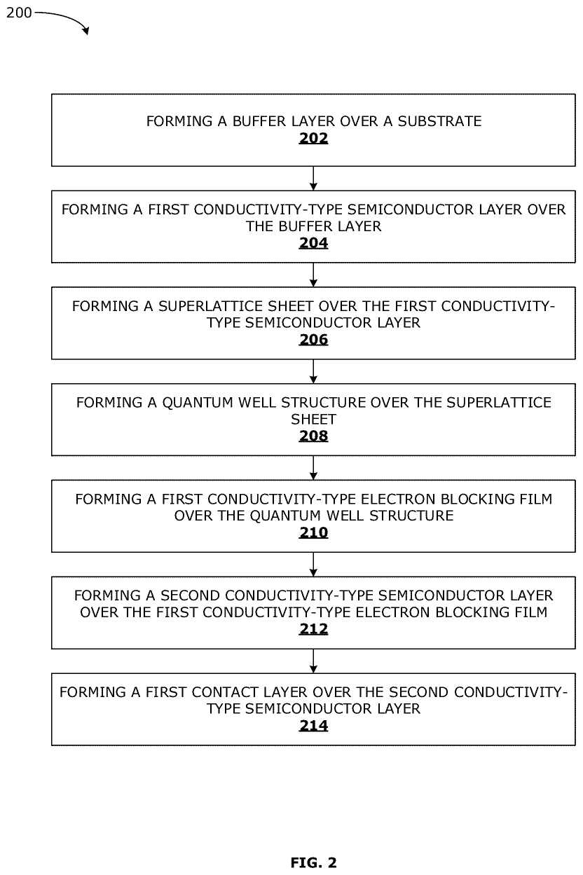

FIG. 2 illustrates a method (200) for fabricating a quantum well-based optoelectronic device, in accordance with embodiments of the present disclosure. At step 202, a buffer layer (104) is formed over a substrate (102). The buffer layer (104) provides a transition region between the substrate (102) and subsequent semiconductor layers, reducing lattice mismatch and minimizing defects. The buffer layer (104) is formed using deposition techniques that establish uniform thickness and material composition.

At step 204, a first conductivity-type semiconductor layer (106) is formed over the buffer layer (104). The first conductivity-type semiconductor layer (106) comprises a first-doped layer (108) and a second-doped layer (110), where the second-doped layer (110) has a lower doping concentration than the first-doped layer (108) by one or two orders of magnitude. The first conductivity-type semiconductor layer (106) is deposited using controlled doping techniques that influence carrier injection and transport properties. The doping concentration gradient between the first-doped layer (108) and the second-doped layer (110) modifies charge carrier mobility and band structure alignment.

At step 206, a superlattice sheet (112) is formed over the first conductivity-type semiconductor layer (106). The superlattice sheet (112) comprises alternating layers of semiconductor materials with controlled thickness and composition. The superlattice sheet (112) modifies carrier transport characteristics by introducing periodic potential barriers and wells. The thickness of each alternating layer in the superlattice sheet (112) is adjusted to influence quantum confinement effects and strain management within the semiconductor stack.

At step 208, a quantum well structure (114) is formed over the superlattice sheet (112). The quantum well structure (114) comprises at least one quantum well layer and at least one barrier layer. The quantum well layer is formed using a semiconductor material with a lower bandgap energy than the adjacent barrier layer to confine charge carriers. The quantum well layer thickness influences recombination properties and emission wavelength. The barrier layer is formed using a material with a higher bandgap energy to restrict carrier movement out of the quantum well region. The barrier layer thickness modifies quantum confinement and carrier coupling properties.

At step 210, a first conductivity-type electron blocking film (116) is formed over the quantum well structure (114). The first conductivity-type electron blocking film (116) comprises a material with a bandgap greater than the quantum well layer, preventing electron overflow while allowing hole transport. The doping profile of the first conductivity-type electron blocking film (116) is controlled to modify charge carrier dynamics.

At step 212, a second conductivity-type semiconductor layer (118) is formed over the first conductivity-type electron blocking film (116). The second conductivity-type semiconductor layer (118) facilitates charge carrier injection and transport. The doping profile of the second conductivity-type semiconductor layer (118) is adjusted along the direction perpendicular to the quantum well structure (114) to modify charge carrier mobility and recombination properties.

At step 214, a first contact layer (120) is formed over the second conductivity-type semiconductor layer (118). The first contact layer (120) establishes an electrical interface for charge carrier extraction. The first contact layer (120) may comprises a tunnel junction that provides a low-resistance electrical contact. The tunnel junction consists of a highly doped semiconductor layer that facilitates quantum mechanical tunneling of charge carriers. The doping concentration of the tunnel junction is controlled to modify contact resistance and carrier injection properties.

In an embodiment, forming the first contact layer (120) may further comprise forming a tunnel junction within the first contact layer (120) to provide a low-resistance electrical contact. The tunnel junction consists of a highly doped semiconductor interface that enables quantum mechanical tunneling of charge carriers, reducing contact resistance. The tunnel junction is formed by introducing a high concentration of dopants into a thin semiconductor region, creating a degenerate p-n junction that facilitates efficient carrier transport. Materials used for the tunnel junction include heavily doped GaN, Indium Tin Oxide (ITO), and InGaN, selected based on band alignment and electrical conductivity. The thickness and doping concentration of the tunnel junction are controlled to balance tunneling probability and series resistance. The tunnel junction is integrated using deposition techniques that enable uniform dopant distribution and interface stability. The selection of tunnel junction parameters is based on carrier transport characteristics and electrical performance requirements.

In an embodiment, forming the quantum well structure (114) may further comprise doping each quantum well layer with a fourth doping element at a preset concentration. The doping of each quantum well layer modifies charge carrier distribution, influencing recombination efficiency and band structure properties. The fourth doping element is introduced based on semiconductor composition and charge carrier dynamics, with examples including Si for n-type doping and Mg for p-type doping. The doping concentration is controlled to maintain a uniform charge carrier density across the quantum well layer, minimizing excess carrier depletion or scattering effects. The introduction of the fourth doping element influences quantum confinement properties by modifying energy band structure and charge carrier lifetime. The incorporation of the fourth doping element is achieved through controlled doping techniques that make sure uniform dopant distribution. Additionally, introduction of dopant can allow higher carrier concentration at low bias condition in the quantum well which will lead to higher radiative recombination and higher bandwidth.

In an embodiment, forming the quantum well structure (114) may further comprise varying the concentration of the fourth doping element along a direction perpendicular to a plane of each quantum well layer to adjust at least one parameter of each quantum well layer, wherein the parameter is selected from an energy band offset, an electron confinement property, and a hole confinement property. A graded doping profile influences charge carrier behavior by creating a gradual transition in electronic properties across the quantum well layer. The variation in doping concentration modifies the energy band offset, controlling charge carrier confinement strength. A higher doping concentration near the quantum well layer interface enhances charge carrier accumulation, whereas a lower doping concentration in central regions influences carrier recombination characteristics. The variation in doping concentration is introduced using controlled doping techniques that establish a spatially varying dopant profile. The selection of doping concentration variation is based on semiconductor material properties, emission wavelength tuning requirements, and charge carrier transport behavior.

In an embodiment, forming the quantum well structure (114) may further comprise alternately and parallelly arranging the quantum well layers and the barrier layers, wherein the quantum well layers and the barrier layers are disposed orthogonally to the superlattice sheet (112). The quantum well structure (114) consists of periodically arranged quantum well layers separated by barrier layers that restrict charge carrier movement. The arrangement of the quantum well layers and the barrier layers influences charge carrier confinement properties and recombination efficiency. The quantum well structure (114) is formed using semiconductor materials selected based on bandgap energy alignment, lattice compatibility, and optical emission characteristics. The parallel arrangement of the quantum well layers and the barrier layers allows for periodic confinement of charge carriers, influencing energy band structure and transition probabilities. The thickness and spacing of the quantum well layers and the barrier layers are adjusted to modify charge carrier movement and recombination dynamics. The integration of the quantum well structure (114) with the superlattice sheet (112) is controlled to maintain structural stability, polarization fields and minimize defect formation.

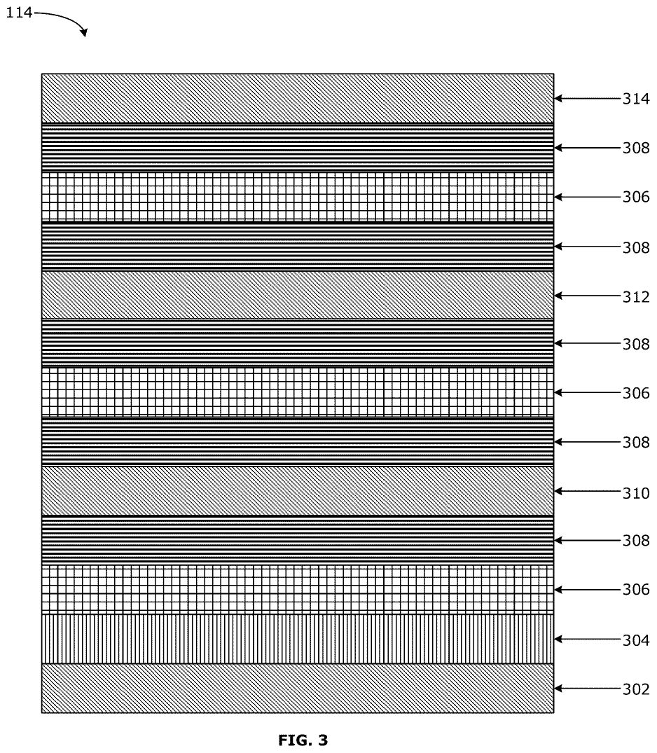

FIG. 3 illustrates an exemplary diagram for a quantum well structure (114) with barrier layers (308) on both sides of each quantum well layer (306), in accordance with embodiments of the present disclosure. The quantum well structure (114) comprises multiple quantum well layers (306) alternating with barrier layers (308) and quantum barriers (302, 310, 312, 314). An interlayer (304) is positioned at the lowest interface of the quantum well structure (114), separating the quantum well layer (306) from the underlying quantum barrier (302).

In an embodiment, the quantum well layers (306) are positioned between barrier layers (308) to facilitate charge carrier confinement and optimize electron-hole recombination efficiency. The quantum well layers (306) may be arranged in different geometrical configurations, such as square, graded, staircase, or coupled quantum well profiles, depending on the application requirements. The choice of quantum well profile influences the spatial overlap of electron and hole wavefunctions, thereby modifying recombination characteristics and emission efficiency. In high-speed optoelectronic applications, selective doping of the quantum well layers (306) can increase carrier concentration, enabling faster carrier dynamics and improved modulation response. The doping concentration within the quantum well layers (306) is adjusted based on operational requirements to maintain efficient radiative recombination while minimizing non-radiative losses.

In an embodiment, the barrier layers (308) are distinct from the quantum barriers (302, 310, 312, 314) and may be fabricated using materials such as AlGaN, AlInN, or AlGaInN. The barrier layers (308) act as confinement layers, preventing carrier leakage and providing strain and polarization engineering. Aforesaid layers also serve as capping layers to protect the quantum well layers (306) from material decomposition during growth. The quantum barriers (302, 310, 312, 314) introduce additional energy barriers to enhance carrier confinement and minimize carrier escape through ballistic transport.

In an embodiment, the interlayer (304) serves to mitigate dopant diffusion into the quantum well layers (306) and may take the same material composition as the barrier layers (308). The presence of the interlayer (304) affirms stable carrier transport and prevents unintentional charge leakage, maintaining the structural integrity and operational efficiency of the quantum well structure (114).

In an embodiment, the quantum barriers (302, 310, 312, 314) are integrated to enhance electron-hole recombination efficiency, increase carrier capture probability, and reduce excess carrier overflow into the first conductivity-type electron blocking film (116). By restricting high-energy carriers, the quantum barriers (302, 310, 312, 314) optimize radiative recombination rates, enabling enhanced optical performance for high-speed optoelectronic applications. In certain configurations, the quantum barriers (302, 310, 312, 314) may also facilitate tunneling current within multi-quantum well (MQW) systems, improving carrier transport properties and overall device efficiency. The barrier layers 308 are optimized to in parallel to reduce any differential resistance incurred to carrier flow between quantum wells. The barrier layers don't need to be of the same composition.

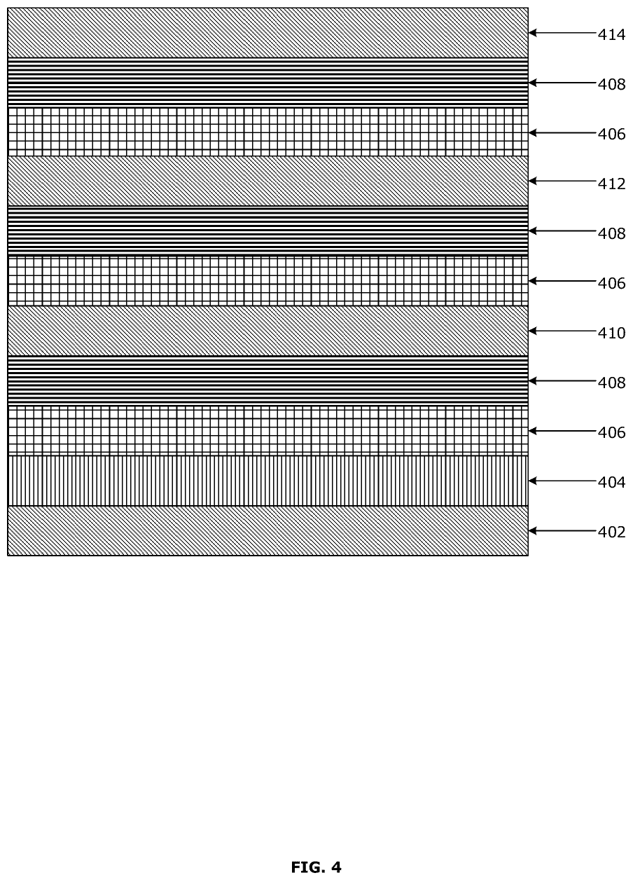

FIG. 4 illustrates an exemplary diagram for a quantum well (406) (similar to the quantum well layer (306) of FIG. 3) with a barrier layer (408) positioned on one side of the quantum well (406), in accordance with embodiments of the present disclosure. The quantum well (406) is integrated within a multilayer semiconductor stack, where the barrier layer (408) (similar to the barrier layer (308) of FIG. 3) is placed to influence radiative recombination by modifying carrier capture characteristics and restricting carrier movement within the quantum well (406). The material composition of the barrier layer (408) includes GaN, InGaN, AlGaN, or a combination thereof, selected based on bandgap properties and lattice compatibility.

In an embodiment, the asymmetric structure of the quantum well (406) incorporates an interlayer (404) (similar to interlayer (304) of FIG. 3) adjacent to the quantum well (406) at the lowest position, preventing dopant diffusion into the active region. The interlayer (404) is composed of a material similar to the barrier layer (408), maintaining consistency in lattice parameters and structural stability. The interlayer (404) prevents unintentional dopant migration, preserving charge carrier properties within the quantum well (406). Quantum barriers (402, 410, 412, 414) are included within the multilayer stack to influence carrier confinement and minimize charge leakage.

In an embodiment, when dopant diffusion is controlled using alternative techniques, the asymmetric quantum well (406) prioritizes maintaining thin quantum well (406) characteristics. The structure is arranged to increase charge carrier capture and recombination rates while minimizing carrier leakage. The quantum barriers (402, 410, 412, 414) influence charge carrier dynamics by limiting high-energy carrier escape from the active region. The barrier layer (408) also contributes to strain and polarization properties, supporting stability and material compatibility in multi-quantum well (MQW)-based optoelectronic devices.

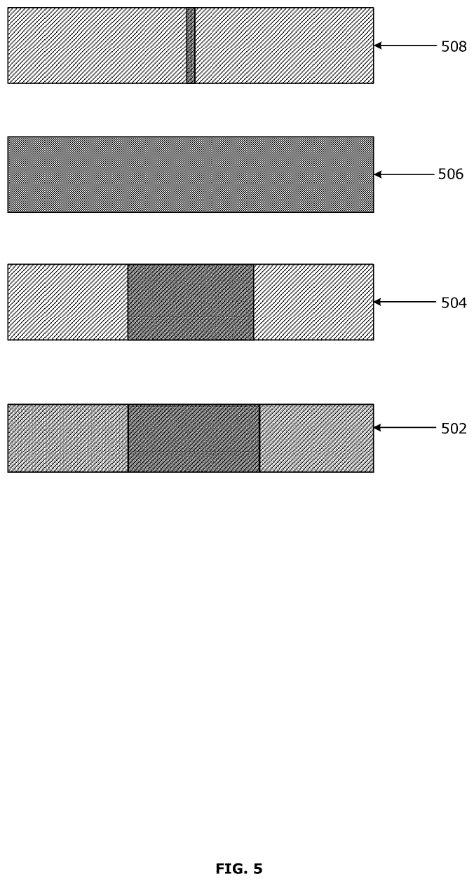

FIG. 5 illustrates various doping schemes for quantum barriers (502, 504, 506, 508) (similar to the quantum barriers (302, 310, 312, 314) of FIG. 3 and the quantum barriers (402, 410, 412, 414) of FIG. 4) to influence carrier dynamics and modify device properties, in accordance with embodiments of the present disclosure. The quantum barrier (508) incorporates a delta-doped layer, introducing localized dopants within a specific region of the quantum barrier (508). Such doping arrangement influences hole injection characteristics while restricting dopant out-diffusion into adjacent layers.

In an embodiment, the quantum barrier (506) employs uniform doping across the entire barrier region. The uniform doping profile modifies resistance characteristics for specific charge carriers, such as holes or electrons, depending on the doping element selection. The uniform doping profile influences carrier transport while preventing charge accumulation at the barrier interface. The quantum barrier (506) is integrated with a barrier layer to restrict dopant diffusion into adjacent layers while maintaining charge carrier injection efficiency.

In an embodiment, the quantum barrier (504) utilizes localized uniform doping in a specific section, modifying carrier movement within the quantum barrier (504). The selected doping arrangement influences carrier transport dynamics in specific regions while maintaining overall structural and material stability. The controlled placement of dopants allows for targeted modification of charge transport pathways, similar to delta doping techniques.

In an embodiment, the quantum barrier (502) integrates a hybrid doping arrangement, where one region features uniform doping, and another region incorporates a graded doping profile. The combination of doping profiles modifies carrier injection while influencing charge transport characteristics. The hybrid doping profile balances charge carrier injection efficiency and doping-induced resistance changes, modifying the operational characteristics of multi-quantum well (MQW)-based optoelectronic devices.

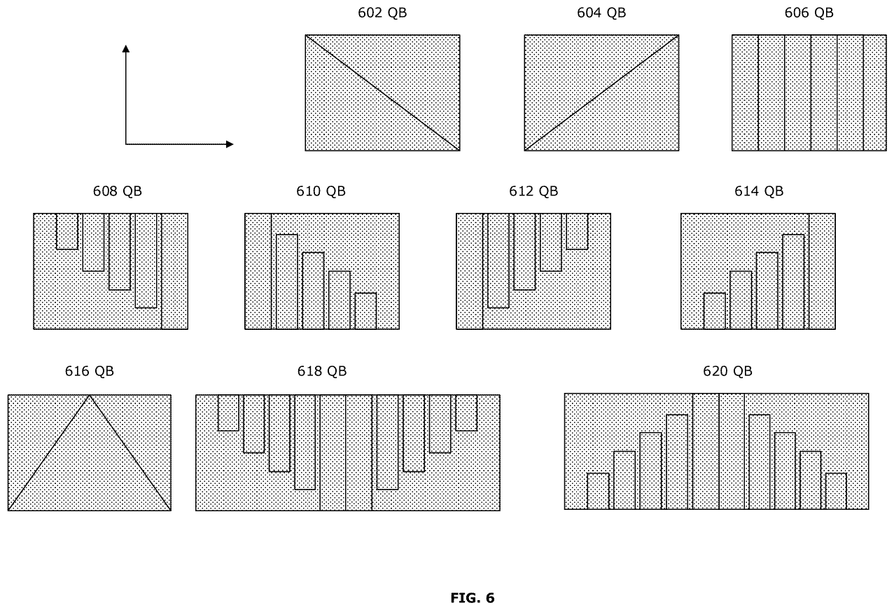

FIG. 6 illustrates various grading schemes implemented in quantum barriers (602, 604, 606, 608, 610, 612, 614, 616, 618, 620) (similar to, the quantum barriers (302, 310, 312, 314) of FIG. 3, the quantum barriers (402, 410, 412, 414) of FIG. 4) and the quantum barriers (502, 504, 506, 508) of FIG. 5) to influence dopant ionization, carrier transport, and barrier height, in accordance with embodiments of the present disclosure. The grading schemes are applied using materials such as GaN, InGaN, AlGaN, AlInN, or AlInGaN, selected based on band alignment and lattice compatibility.

In an embodiment, the quantum barriers (602, 604) implement linear, parabolic, quadratic, or logarithmic grading to introduce a gradual material composition transition. The continuous grading profile modifies potential energy distribution, influencing dopant ionization and carrier tunneling across the barrier. The grading profile enables efficient charge injection into adjacent quantum well layers while modifying resistance characteristics for high-speed operation.

In an embodiment, the quantum barrier (606) utilizes abrupt material transition, creating a sharp energy step that influences charge carrier confinement and tunneling dynamics. The distinct energy barrier modification prevents unwanted carrier overflow while promoting tunneling-assisted charge transport within the multi-quantum well (MQW) system.

In an embodiment, the quantum barriers (608, 610) incorporate a superlattice structure with downward grading. The periodic potential profile modifies charge carrier transport by directing movement along specific pathways, reducing strain accumulation within the barrier. The material composition gradient influences dopant ionization efficiency for enhanced carrier movement.

In an embodiment, the quantum barriers (612, 614) integrate an upward-graded superlattice structure, creating a gradually increasing potential that modifies carrier tunneling characteristics. The potential variation influences transport efficiency while minimizing ballistic transport effects. The asymmetric grading profile introduces strain-relief properties while modifying doping efficiency.

Design based on 606-614 provides a design flexibility to balance barrier height and carrier flow of one type of carrier.

Quantum barrier (616, 618, 620) combines features from the linear grading in schemes 602 and 604 providing a optimized barrier height and carrier flow rate. This hybrid approach provides enhanced flexibility, offering both a gradual potential change for carrier injection and a periodic potential for strain relief and carrier confinement. By combining these advantages, this scheme can optimize dopant ionization, minimize leakage, and ensures efficient tunneling, making it suitable for advanced high-speed and high-efficiency devices.

Quantum barrier (618, 620) takes advantage of SL and graded layer to be implemented enhancing the performance attributed with both type of the carriers. Grading implementation does not have to be symmetric for optimum design.

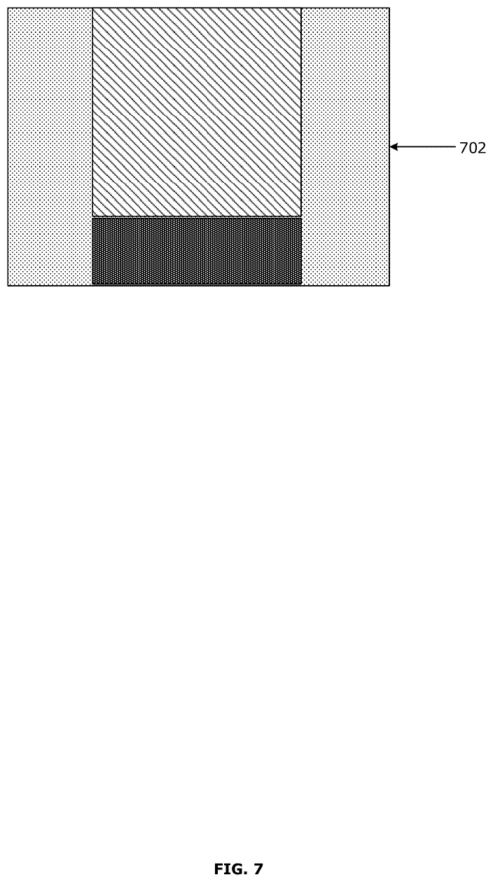

FIG. 7 illustrates a quantum barrier (702) (similar to, the quantum barriers (302, 310, 312, 314) of FIG. 3, the quantum barriers (402, 410, 412, 414) of FIG. 4), the quantum barriers (502, 504, 506, 508) of FIG. 5) and the quantum barriers (602, 604, 606, 608, 610, 612, 614, 616, 618, 620) of FIG. 6) incorporating co-doping to modify dopant ionization properties and stabilize charge carrier characteristics, in accordance with embodiments of the present disclosure. The co-doping approach introduces elements such as Si, zinc (Zn), calcium (Ca), germanium (Ge), and beryllium (Be) into the quantum barrier (702) to influence dopant activation and prevent dopant diffusion into adjacent quantum well layers. In applications where Mg is used as a p-type dopant, co-doping with Si introduces n-type carriers that form coulombic interactions with Mg acceptors, restricting Mg mobility and minimizing its diffusion during high-temperature processing. The interaction between co-dopants and Mg acceptors stabilizes the lattice structure, reducing thermal migration effects and preserving charge carrier distribution. Specific co-dopants such as oxygen (O) facilitate hydrogen removal from Mg dopants, improving p-type activation by breaking Mg—H complexes formed during semiconductor growth. Zinc (Zn) modifies Mg—H complex formation by introducing alternative acceptor sites, reducing hydrogen passivation effects and promoting charge carrier mobility. The presence of co-dopants in the quantum barrier (702) also influences hole concentration within the barrier region, modifying carrier injection efficiency and mitigating polarization-induced electric fields in III-nitride semiconductor structures. The combination of co-doping and optimized annealing conditions facilitate enhanced p-type conductivity and improved material stability for optoelectronic applications. The co-doping approach provides additional benefits, including controlled carrier flow across the quantum barrier (702) and improved overlap of electron-hole wavefunctions within the quantum well layers, influencing radiative recombination efficiency and device performance.

In an embodiment, quantum well structure (114) positioned over superlattice sheet (112) facilitates carrier confinement, modifying radiative recombination efficiency and emission wavelength characteristics. The alternating arrangement of quantum well layers and barrier layers modify charge carrier wavefunction overlaps, influencing transition probability and optical emission characteristics. Barrier layers introduce potential barriers that influence carrier escape probability, modifying charge carrier confinement.

In an embodiment, doping concentration of second-doped layer (110) being lower than first-doped layer (108) by one or two orders modifies charge carrier distribution, influencing electric field properties and charge carrier transport efficiency. The doping concentration gradient between first-doped layer (108) and second-doped layer (110) influences carrier injection characteristics, modifying carrier recombination efficiency. Table. 1 illustrates the effect of doping concentration over the charge carrier distribution, the electric field properties and the charge carrier transport efficiency.

TABLE 1

| Doping | Electric | Charge | Recombination Losses |
|---|---|---|---|
| Concentration | Field | Carrier | Outside Quantum Well |
| Increase | Distribution | Mobility | Structure (114) |
| Baseline (0% | ★★☆☆☆ | ★★★★★ | ★★★★☆ |
| increase) | (Weak) | (High) | (High) |
| +5% increase | ★★★☆☆ | ★★★★☆ | ★★★☆☆ |
| | (Moderate) | (Slightly High) | (Moderate) |
| +7% increase | ★★★★☆ | ★★★☆☆ | ★★☆☆☆ |
| | (Strong) | (Moderate) | (Low) |
| +10% increase | ★★★★★ | ★★☆☆☆ | ★☆☆☆☆ |
| | (Very Strong) | (Lower) | (Very Low) |

An increase in doping concentration enhances electric field distribution while reducing charge carrier mobility. Higher doping reduces recombination losses outside the quantum well structure (114), improving carrier confinement and radiative recombination efficiency. However, excessive doping lowers charge carrier mobility due to impurity scattering.

In an embodiment, barrier layer comprising a graded material composition along a direction perpendicular to a plane of barrier layer modifies band alignment, influencing charge carrier confinement and transport properties. The graded composition profile introduces a gradual energy transition that influences carrier recombination rates and tunneling probabilities.

In an embodiment, barrier layer doped with first doping element introduces localized charge carriers, influencing potential energy distribution and carrier injection characteristics. The first set of areas comprising first doping element modifies carrier recombination rates, while second set of areas free from first doping element influences electric field distribution.

In an embodiment, first doping element in first set of areas introduced using delta doping, uniform doping, or graded doping technique modifies dopant distribution characteristics, influencing charge carrier mobility and recombination efficiency. The choice of doping technique influences spatial carrier distribution and electric field properties within barrier layer.

In an embodiment, at least one of first set of areas co-doped with second doping element selected from silicon, germanium, beryllium, calcium, and zinc modifies carrier transport properties, influencing charge carrier injection efficiency. The interaction between first and second doping elements modifies dopant activation energy, influencing charge carrier mobility. Table. 2 illustrates the effect of co-doping over the carrier transport properties and the charge carrier injection efficiency.

TABLE 2

| | Carrier | Charge Carrier | Charge |
|---|---|---|---|
| Co-Doping | Transport | Injection | Carrier |
| Configuration | Properties | Efficiency | Mobility |
| Baseline (Single | ++ | ++ | ++++ |
| Doping Element) | (Moderate) | (Moderate) | (High) |
| Co-Doping with | ++++ | ++++ | +++ |
| Low Concentration | (Strong) | (High) | (Slightly High) |
| Co-Doping with | +++++ | +++++ | ++ |
| Moderate | (Very Strong) | (Very High) | (Moderate) |
| Concentration | | | |
| Co-Doping with | +++ | +++ | + |
| High | (Moderate) | (Moderate) | (Low) |
| Concentration | | | |

Moderate co-doping improves carrier transport properties and enhances charge carrier injection efficiency by optimizing dopant activation energy. However, excessive co-doping increases impurity scattering, reducing charge carrier mobility and potentially affecting overall device performance.

In an embodiment, each quantum well layer and each barrier layer associated with a variable thickness modifies emission wavelength by influencing quantum confinement effects. Thickness variation modifies charge carrier recombination efficiency, influencing optical emission properties and wavelength tuning characteristics.

In an embodiment, second conductivity-type semiconductor layer (118) doped with third doping element introduces a doping gradient along a direction perpendicular to a plane of quantum well layer and barrier layer, modifying carrier injection efficiency and charge carrier distribution characteristics. The doping concentration gradient influences carrier transport properties and electric field stability.

In an embodiment, thickness of each layer of semiconductor material in superlattice sheet (112) being uniform influences electronic band structure and charge carrier transport uniformity. The uniformity in thickness modifies periodic potential characteristics, influencing carrier recombination and injection efficiency.

In an embodiment, thickness of each layer of semiconductor material in superlattice sheet (112), being non-uniform modifies carrier confinement characteristics, influencing electronic band structure and tunneling probabilities. The non-uniform thickness profile modifies charge carrier transport efficiency.

In an embodiment, interlayer disposed at an interface between each quantum well layer and each adjacent barrier layer modifies strain distribution and carrier injection properties. The interlayer influences material compatibility and electric field stability.

In an embodiment, first contact layer (120) comprising a tunnel junction modifies electrical contact resistance, influencing charge carrier injection efficiency. The tunnel junction introduces quantum mechanical tunneling properties, modifying contact resistance and charge carrier transport efficiency.

In an embodiment, each quantum well layer doped with fourth doping element at a preset concentration modifies charge carrier density, influencing recombination efficiency and charge carrier confinement characteristics. The doping concentration modifies charge transport and emission wavelength characteristics.

In an embodiment, concentration of fourth doping element varying in a direction perpendicular to a plane of each quantum well layer modifies an energy band offset, an electron confinement property, and a hole confinement property. The doping gradient influences charge carrier recombination rates and tunneling probabilities.

In an embodiment, quantum well structure (114) comprising quantum well layers and barrier layers alternately and parallelly arranged, wherein quantum well layers and barrier layers are disposed orthogonally to superlattice sheet (112), modifies charge carrier transport dynamics and recombination efficiency. The layer arrangement influences carrier movement and energy transition properties.

In an embodiment, first conductivity-type semiconductor layer (106) comprising a stacked semiconductor arrangement with alternating layers of GaN, InGaN, AlGaN, AlInN, and AlGaInN modifies material compatibility and charge carrier injection efficiency. The stacked semiconductor arrangement influences electronic band alignment and strain distribution properties.

In an embodiment, first conductivity-type electron blocking film (116) fabricated from a material with a bandgap greater than quantum well layer modifies electron confinement characteristics, influencing charge carrier transport efficiency. The blocking film introduces potential barriers that influence charge carrier injection and recombination properties.

In an embodiment, second conductivity-type semiconductor layer (118) comprising a temperature-stabilized doped region modifies charge carrier mobility and recombination efficiency under varying thermal conditions. The doping profile influences temperature stability characteristics and charge carrier transport properties.

In an embodiment, forming a buffer layer (104) over a substrate (102) modifies lattice compatibility, influencing charge carrier mobility and strain distribution properties. The buffer layer (104) provides a transition region that modifies material stability characteristics.

In an embodiment, forming first conductivity-type semiconductor layer (106) over buffer layer (104), wherein first conductivity-type semiconductor layer (106) comprises first-doped layer (108) and second-lower doped layer (110), modifies charge carrier injection properties and electric field stability. The doping concentration profile influences charge transport and recombination efficiency.

In an embodiment, forming superlattice sheet (112) over first conductivity-type semiconductor layer (106), wherein superlattice sheet (112) comprises alternating layers of semiconductor materials, modifies electronic band structure characteristics and charge carrier transport properties. The alternating layer arrangement modifies quantum confinement and tunneling probabilities.

In an embodiment, forming quantum well structure (114) over superlattice sheet (112), wherein quantum well structure (114) comprises at least one quantum well layer and at least one barrier layer, modifies charge carrier confinement properties and recombination efficiency. The quantum well structure (114) influences emission wavelength and charge carrier transport characteristics.

In an embodiment, forming first conductivity-type electron blocking film (116) over quantum well structure (114) modifies electron overflow characteristics and charge carrier injection efficiency. The blocking film introduces an energy barrier that modifies charge carrier movement and recombination properties.

In an embodiment, forming second conductivity-type semiconductor layer (118) over first conductivity-type electron blocking film (116) modifies charge carrier transport and injection properties. The semiconductor layer introduces material compatibility characteristics that influence charge carrier mobility.

In an embodiment, forming first contact layer (120) over second conductivity-type semiconductor layer (118) modifies electrical interface properties and charge carrier injection efficiency. The first contact layer (120) influences resistance characteristics and charge carrier transport properties.

In an embodiment, forming a tunnel junction within first contact layer (120) modifies electrical contact resistance and charge carrier injection efficiency. The tunnel junction introduces quantum mechanical tunneling characteristics that influence carrier movement properties.

In an embodiment, doping each quantum well layer with fourth doping element at the present concentration modifies charge carrier density and recombination efficiency. The doping concentration profile influences charge carrier mobility characteristics.

In an embodiment, varying the concentration of fourth doping element along a direction perpendicular to a plane of each quantum well layer modifies an energy band offset, an electron confinement property, and a hole confinement property. The doping gradient influences charge carrier distribution characteristics.

In an embodiment, forming quantum well structure (114) comprising quantum well layers and barrier layers alternately and parallelly arranged, wherein quantum well layers and barrier layers are disposed orthogonally to superlattice sheet (112), modifies charge carrier transport properties and recombination efficiency. The alternating layer arrangement influences carrier dynamics and quantum confinement characteristics.

What is claimed is:

1. A quantum well-based optoelectronic device comprising:
a buffer layer disposed over a substrate;
a first conductivity-type semiconductor layer positioned over the buffer layer, wherein the first conductivity-type semiconductor layer comprises a first-doped layer and a second-doped layer;
a undoped or lightly doped layer to reduce depletion capacitance
a superlattice sheet positioned over the first conductivity-type semiconductor layer, wherein the superlattice sheet comprises the alternating layers of the semiconductor materials;
a quantum well structure positioned over the superlattice sheet, wherein the quantum well structure comprises:
at least one quantum well layer; and
at least one barrier layer;
a first conductivity-type electron blocking film positioned over the quantum well structure;
a second conductivity-type semiconductor layer disposed over the first conductivity-type electron blocking film; and
a first contact layer disposed over the second conductivity-type semiconductor layer.

2. The quantum well-based optoelectronic device of claim 1, wherein doping concentration of the second-doped layer is lower than doping concentration of the first-doped layer by one to two orders of magnitude.

3. The quantum well-based optoelectronic device of claim 1, wherein the barrier layer comprises a graded material composition along a direction perpendicular to a plane of the barrier layer to modify a band alignment.

4. The quantum well-based optoelectronic device of claim 1, wherein the barrier layer is dopped with a first doping element, wherein the barrier layer comprises a first set of area which comprises the first doping element, and a second set of area which is free from the first doping element.

5. The quantum well-based optoelectronic device of claim 4, wherein the first doping element in each of the first set of area is introduced using at least one selected from: a delta doping technique, a uniform doping technique, and a graded doping technique.

6. The quantum well-based optoelectronic device of claim 1, wherein the at least one of the first set of area is co-doped with a second doping element selected from a group comprising silicon, germanium, beryllium, calcium, and zinc.

7. The quantum well-based optoelectronic device of claim 1, wherein each quantum well layer and each barrier layer are associated with a variable thickness to control emission wavelength and optimize electron-hole recombination.

8. The quantum well-based optoelectronic device of claim 1, wherein the second conductivity-type semiconductor layer is dopped with a third doping element, wherein concentration of the third doping element changes along direction perpendicular to the plane of the quantum well layer and the barrier layer.

9. The quantum well-based optoelectronic device of claim 1, wherein thickness of each layer of the semiconductor material in the superlattice sheet is uniform.

10. The quantum well-based optoelectronic device of claim 1, wherein thickness of each layer of the semiconductor material in the superlattice sheet is non-uniform.

11. The quantum well-based optoelectronic device of claim 1, wherein an interlayer is disposed at an interface between each quantum well layer and each adjacent barrier layer.

12. The quantum well-based optoelectronic device of claim 1, wherein the first contact layer comprises a tunnel junction to provide a low-resistance electrical contact.

13. The quantum well-based optoelectronic device of claim 1, wherein each quantum well layer is, individually, dopped with a fourth doping element.

14. The quantum well-based optoelectronic device of claim 1, wherein concentration of the fourth doping element varies in direction perpendicular to the plane of the quantum well layer to adjust at least one parameter of the each quantum well layer, wherein the parameter is selected from an energy band offset and an electron confinement property and a hole confinement property.

15. The quantum well-based optoelectronic device of claim 1, wherein the quantum well structure comprises the quantum well layers and the barrier layers alternately and parallelly arranged, wherein the quantum well layers and the barrier layers are disposed of orthogonally to the superlattice sheet.

16. The quantum well-based optoelectronic device of claim 1, wherein the first conductivity-type semiconductor layer comprises a stacked semiconductor arrangement, wherein the stacked semiconductor arrangement comprises the alternating layers of a semiconductor composition selected from a group comprising Gallium Nitride (GaN), Indium Gallium Nitride (InGaN), AlGaN, Aluminum Indium Nitride (AlInN), and Aluminum Gallium Indium Nitride (AlGaInN).

17. The quantum well-based optoelectronic device of claim 1, wherein the first conductivity-type electron blocking film is fabricated from a material with a bandgap greater than the quantum well layer.

18. The quantum well-based optoelectronic device of claim 1, wherein the second conductivity-type semiconductor layer comprises a temperature-stabilized doped region.

19. A method for fabricating a quantum well-based optoelectronic device, comprising:
forming a buffer layer over a substrate;
forming a first conductivity-type semiconductor layer over the buffer layer, wherein the first conductivity-type semiconductor layer comprises a first-doped layer and a second-doped layer;
forming a superlattice sheet over the first conductivity-type semiconductor layer, wherein the superlattice sheet comprises the alternating layers of the semiconductor materials;
forming a quantum well structure over the superlattice sheet, wherein the quantum well structure comprises:
forming at least one quantum well layer; and
forming at least one barrier layer on either side of the quantum well layer;
forming a first conductivity-type electron blocking film over the quantum well structure;
forming a second conductivity-type semiconductor layer over the first conductivity-type electron blocking film; and
forming a first contact layer over the second conductivity-type semiconductor layer.

20. The method of claim 19, further comprises a tunnel junction within the first contact layer to provide a low-resistance electrical contact.

21. The method of claim 19, further comprises doping each quantum well layer with a fourth doping element.

22. The method of claim 21, wherein the quantum well can be configured in various profiles, including square, graded, staircase, or coupled quantum wells.

23. The method of claim 21, wherein the quantum well can have carrier localization region.

24. The method of claim 23, wherein concentration of the fourth doping element varies along a direction perpendicular to a plane of each quantum well layer to adjust at least one parameter of each quantum well layer, wherein the parameter is selected from an energy band offset, an electron confinement property, and a hole confinement property.

25. The method of claim 21, wherein forming the quantum well structure comprises alternately and parallelly arranging the quantum well layers and the barrier layers, wherein the quantum well layers and the barrier layers are disposed of orthogonally to the superlattice sheet.
